(19) United States
(12) Patent Application Publication
(10) Pub. No.: US 2025/0329701 A1
(43) Pub. Date: Oct. 23, 2025

(54) SEMICONDUCTOR PACKAGE STRUCTURE WITH INTERPOSER DIES

(71) Applicant: Taiwan Semiconductor Manufacturiing Co., Ltd., Hsinchu (TW)

(72) Inventors: Tso-Jung Chang, Taoyuan City (TW); Chih-Peng Lin, Hsinchu (TW); Jeng-Shien Hsieh, Kaohsiung (TW); Chieh-Yen Chen, Taipei City (TW); Hung-Yi Kuo, Taipei City (TW); Han-Jong Chia, Hsinchu (TW)

(21) Appl. No.: 19/258,018

(22) Filed: Jul. 2, 2025

Related U.S. Application Data
(63) Continuation of application No. 18/680,053, filed on May 31, 2024.
(60) Provisional application No. 63/622,116, filed on Jan. 18, 2024.

(51) Int. Cl. H01L 25/18; H01L 21/48; H01L 23/00; H01L 23/14; H01L 23/498

(52) U.S. Cl. CPC H01L 25/18; H01L 21/486; H01L 23/147; H01L 23/49822; H01L 23/49833; H01L 24/08; H01L 24/16; H01L 24/80; H01L 24/04; H01L 2224/0401; H01L 2224/08145; H01L 2224/08225; H01L 2224/16145; H01L 2224/80895; H01L 2224/80896; H01L 2924/1434

(57) ABSTRACT

In an embodiment, a semiconductor device may include an interposer. The semiconductor device may also include a plurality of chiplets directly bonded to the interposer. The device may furthermore include a plurality of interposer dies directly bonded to the interposer adjacent to the plurality of chiplets, the plurality of interposer dies having through-substrate vias. The device may additionally include a memory package over and bonded to at least one of the plurality of interposer dies.

### PRIORITY CLAIM AND CROSS-REFERENCE

This application is a continuation of U.S. patent application Ser. No. 18/680,053, filed on May 31, 2024, which claims the benefit of U.S. Provisional Application No. 63/622,116, filed on Jan. 18, 2024, which applications are hereby incorporated herein by reference.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged. An example of such packaging systems is Package-on-Package (POP) technology. In a POP device, a top semiconductor package is stacked on top of a bottom semiconductor package to provide a high level of integration and component density. PoP technology generally enables production of semiconductor devices with enhanced functionalities and small footprints on a printed circuit board (PCB).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 through 10 are cross-sectional views and a top view of intermediate steps of a process for forming a semiconductor package in accordance with some embodiments.

FIGS. 11 through 12 are cross-sectional views of intermediate steps of a process for forming a semiconductor package in accordance with some embodiments.

FIG. 13 is a cross-sectional view of an intermediate step of a process for forming a semiconductor package in accordance with some embodiments.

FIG. 14 is a cross-sectional view of an intermediate step of a process for forming a semiconductor package in accordance with some embodiments.

FIG. 15 is a cross-sectional view of an intermediate step of a process for forming a semiconductor package in accordance with some embodiments.

FIGS. 16 through 17 are cross-sectional views of intermediate steps of a process for forming a semiconductor package in accordance with some embodiments.

FIG. 18 is a cross-sectional view of an intermediate step of a process for forming a semiconductor package in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure relates to the field of semiconductor devices, and more specifically, to the integration of system on integrated chip (SoIC) chiplets, one or more bumped memory dies in a modularized application processor. In semiconductor technology, the integration of various components such as SoIC chiplets (may also be referred to as IC dies), memory dies, and power management integrated circuits (PMIC) for application processors (AP) presents a technical challenge. This challenge is primarily due to the lack of a solution that can effectively integrate these components while maintaining low latency and high bandwidth.

Addressing this technical problem, the present disclosure introduces an approach that involves the use of adapter interposer dies or through dielectric vias. This approach enables the use of direct bonding and bumps in the structure. This solution is not just suitable for APs, but also cost-effective as it enables SoIC chiplets with no through-silicon vias (TSV) in active dies. Furthermore, it offers better efficiency allowing for the choice of an appropriate node for the SoIC chiplets and shorter interconnect length between SoIC chiplets due to the surrounding adapter interposer dies.

In some embodiments, features of the disclosure include the adapter interposer dies being power interface dies/active interposer die (PIDs/AIDS) surrounding CPU/xPU dies, using TSVs in the PIDs/AIDs to replace conventional through InFO vias (TIVs) in an integrated fan-out (InFO) package, and bonding the PIDs/AIDs and CPU/xPU dies to an underlying interposer using an SoIC bond technique (e.g., a direct bonding technique). In addition, some embodiments may include adding an additional support substrate over the CPU/xPU dies to improve heat dissipation. Furthermore, an additional power management IC can be added to coordinate power requirements of CPU, xPU, and memory dies, as these dies may have different power domains. The SoIC bonding includes dielectric-to-dielectric bonding and, in some embodiments, can provide a vertical stacking interface for two silicon photonic dies.

The present disclosure provides a solution to the technical problem of integrating various components in a modularized application processor. By introducing an interposer dies or through dielectric vias, the disclosure offers a way to achieve lower latency and higher bandwidth, enhancing the performance of the application processor. The inventive features and benefits of the disclosure will be further elaborated in the following sections.

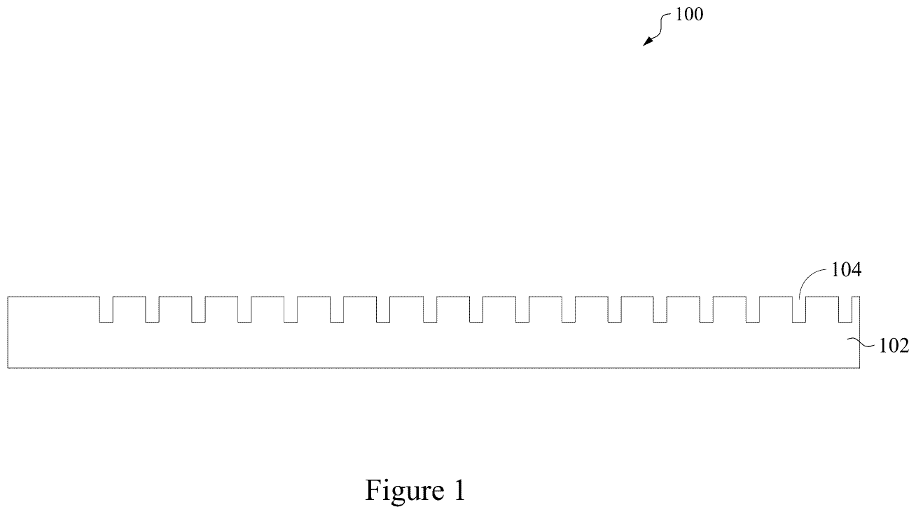

FIGS. 1 through 10 are cross-sectional views and a top view of intermediate steps of a process for forming a semiconductor package 100 in accordance with some embodiments. The semiconductor package 100 includes an interposer with chiplets (or dies) and adapter dies bonded to the interposer. The chiplets and adapter dies may be encapsulated.

Referring to FIG. 1, a cross-sectional view of an intermediate stage of processing a package structure 100 is depicted. The package structure 100 includes a substrate 102, which may serve as the base layer of the package structure 100. The substrate 102 may be formed from various materials, including but not limited to silicon, glass, ceramic, or any other suitable material. In some embodiments, the substrate 102 may be an interposer 110, which may be made of a silicon material. The interposer 110 may serve as a foundational layer for the integration of various components, such as SoIC chiplets, dies, adapter dies, and memory packages.

The substrate 102 includes a series of trenches 104 formed within it. In some embodiments, the trenches 104 are uniformly distributed across the substrate 102. The trenches 104 may be formed using by various patterning techniques, such as etching or laser ablation. The trenches 104 may be filled with a dielectric material, a conductive material, or left empty, depending on the specific requirements of the package structure 100. In some embodiments, the trenches 104 will have deep trench capacitors formed therein.

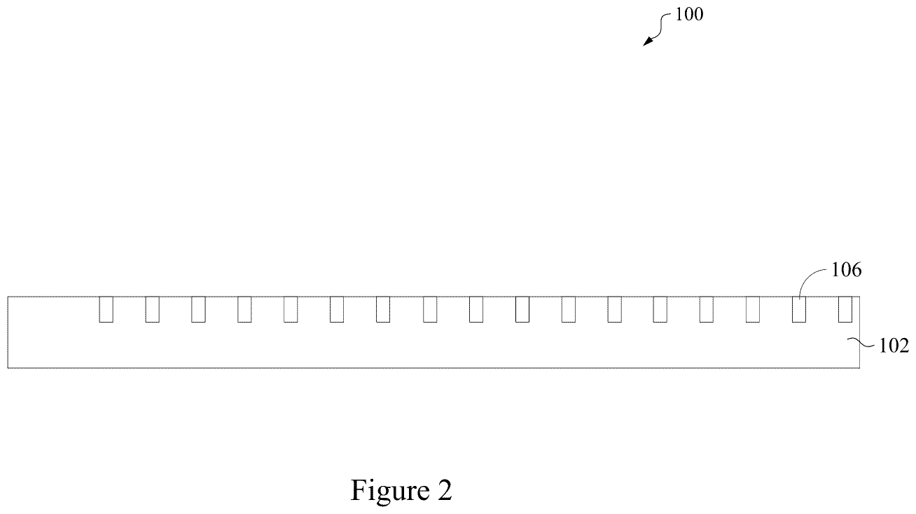

In FIG. 2, the package structure 100 is shown with a series of deep trench capacitors 106 formed in the trenches 104 within the substrate 102. The deep trench capacitors 106 may be formed using various techniques known in the art, such as deposition and etching processes. The deep trench capacitors 106 may serve as energy storage devices, providing power supply decoupling, noise filtering, or other functions within the package structure 100.

In some embodiments, the deep trench capacitors 106 may be formed from multiple layers of dielectric material conductive material. In some embodiments, the dielectric and conductive material are alternating with the dielectric layers being sandwiched between two conductive layers. The dielectric material may be an oxide, a nitride, a high-k dielectric material, or any other suitable dielectric material. The conductive layers may be formed from a metal (e.g., copper, or the like), a semiconductor, a conductive polymer, or any other suitable conductive material.

In some embodiments, the deep trench capacitors 106 may be replaced with other types of passive components, such as resistors or inductors, depending on the specific requirements of the package structure 100. Alternatively, the trenches 104 and deep trench capacitors 106 may be omitted, the trenches left empty or filled with a dielectric material for isolation purposes.

The formation of the deep trench capacitors 106 within the trenches 104 represents an efficient use of the available space within the substrate 102, allowing for the integration of additional components within the package structure 100. This may result in a more compact and efficient design, potentially leading to improved performance and reduced cost.

The configuration of the package structure 100 as depicted in FIG. 2 is one example of how the deep trench capacitors 106 may be integrated within the substrate 102. Other configurations and arrangements of the deep trench capacitors 106 within the substrate 102 are also possible, depending on the specific requirements of the package structure 100.

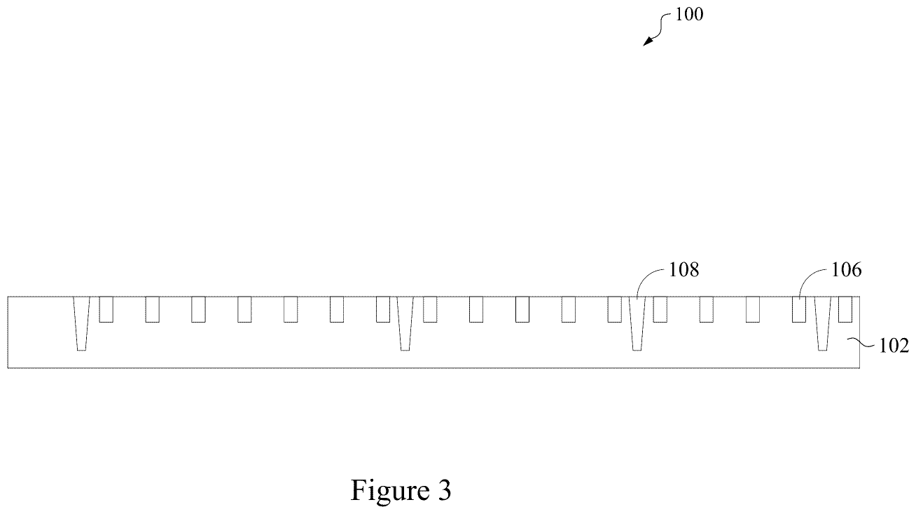

FIG. 3 illustrates the formation of through substrate vias 108 in the substrate 102. The through substrate vias 108 may be formed using various patterning techniques, such as laser drilling, etching, or other suitable methods. Initially, the through substrate vias 108 may extend only partially through the substrate 102 and may not extend to the backside of the substrate 102 until after a thinning process.

In some embodiments, the through substrate vias 108 are filled with a conductive material to provide electrical connectivity between different layers or components of the package structure 100. The conductive material may be a metal, a doped semiconductor, a conductive polymer, or any other suitable conductive material. In some embodiments, the through substrate vias 108 may be lined with a barrier layer or a seed layer before being filled with the conductive material. The barrier layer may be formed from a material such as titanium, titanium nitride, tantalum, tantalum nitride, or any other suitable barrier material. The seed layer may be formed from a material such as copper, gold, silver, or any other suitable seed material.

Various configurations and arrangements of the through substrate vias 108 within the substrate 102 are possible, depending on the specific requirements of the package structure 100. For instance, the through substrate vias 108 may be arranged in a regular grid pattern, a staggered pattern, a random pattern, or any other suitable pattern. The size, shape, and spacing of the through substrate vias 108 may also be varied, depending on the specific requirements of the package structure 100.

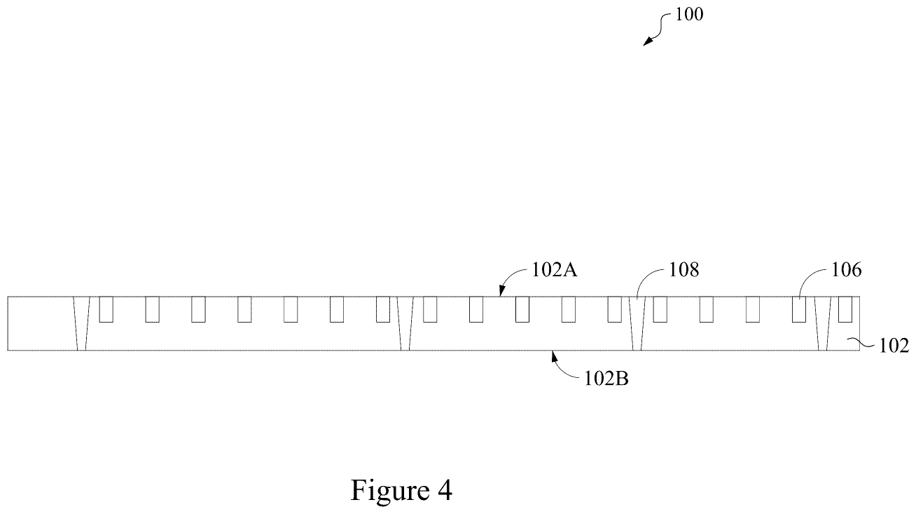

FIG. 4 illustrates the thinning of the back-side surface 102B of the substrate 102. In some embodiments, the thinning process may include a planarization process such as chemical mechanical polishing (CMP), grinding, etching, or other suitable methods. The thinning process may be controlled to achieve a desired thickness of the substrate 102, which may depend on the specific requirements of the package structure 100. In some embodiments, the thinning process may be performed until the through substrate vias 108 are exposed at the back-side surface 102B of the substrate 102. After the thinning, the through substrate vias 108 extend through the substrate 102, from the front-side surface 102A to the back-side surface 102B.

The exposure of the through substrate vias 108 at the back-side surface 102B may facilitate the formation of electrical connections to the through substrate vias 108 from the back-side of the substrate 102. These electrical connections may be used to connect the through substrate vias 108 to other components or layers of the package structure 100, such as integrated circuit dies, interposer dies, memory packages, or other components.

In some embodiments, the thinning process may also expose the deep trench capacitors 106 at the back-side surface 102B of the substrate 102. This may facilitate the formation of electrical connections to the deep trench capacitors 106 from the back-side of the substrate 102. These electrical connections may be used to connect the deep trench capacitors 106 to other components or layers of the package structure 100, such as integrated circuit dies, interposer dies, memory packages, or other components.

The thinning of the back-side surface 102B and the exposure of the through substrate vias 108 and the deep trench capacitors 106 represent an efficient way to provide electrical connectivity within the package structure 100. This may result in improved signal transmission, reduced signal delay, and increased bandwidth, potentially leading to improved performance of the package structure 100.

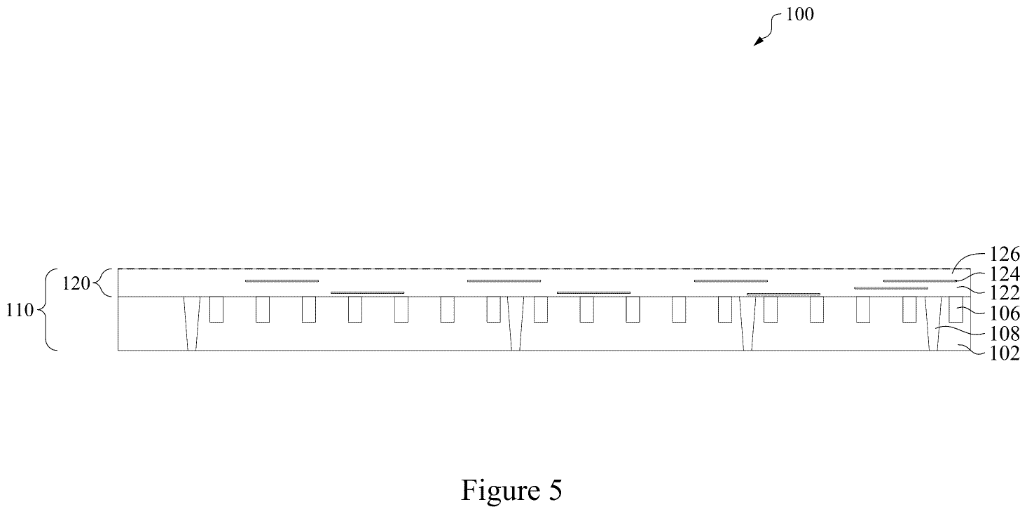

FIG. 5 illustrates the formation of an interconnect structure 120 on the front-side surface 102A of the substrate 102 of the interposer 110. The interconnect structure 120 may include of multiple dielectric layers 122 and metallization layers 124. The dielectric layers 122 may be formed from various dielectric materials, such as silicon dioxide, silicon nitride, low-k dielectric materials, high-k dielectric materials, or any other suitable dielectric materials. The metallization layers 124 may be formed from various conductive materials, such as copper, aluminum, gold, silver, or any other suitable conductive materials.

In some embodiments, the interconnect structure 120 may be formed using various techniques, such as deposition and patterning processes including damascene processes. The interconnect structure 120 may include a bonding surface 126 at the top, where components will be subsequently bonded. The bonding surface 126 may include metallization structure such as bond pads, a dielectric material, or a combination thereof.

The interconnect structure 120 may facilitate electrical connections between various components of the package structure 100, such as integrated circuit dies, interposer dies, memory packages, or other components. The electrical connections may be formed through the metallization layers 124 and the through substrate vias 108, providing both horizontal and vertical electrical connectivity within the package structure 100.

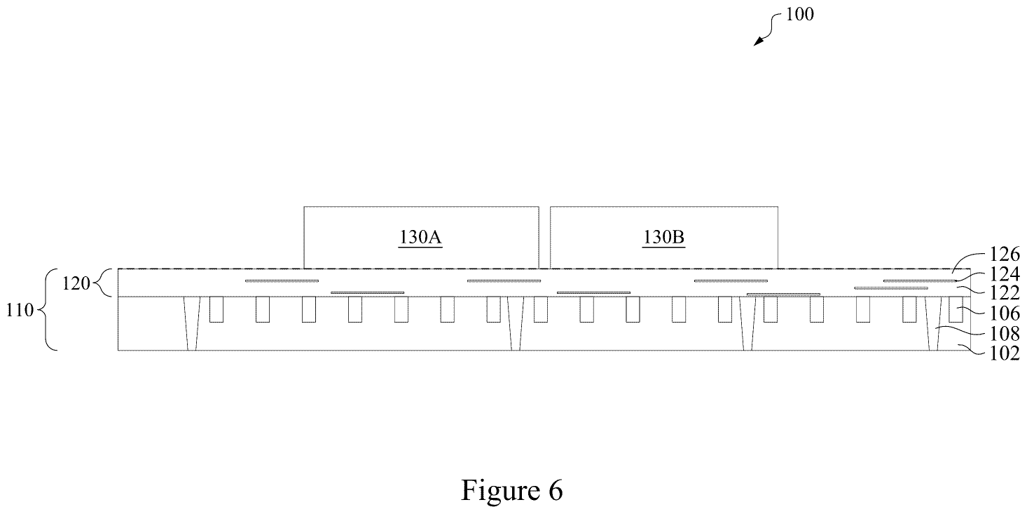

FIG. 6 illustrates the bonding of the integrated circuit dies 130A and 130B to the interconnect structure 120. The integrated circuit dies 130 may also be referred to as chiplets 130. The interconnect structure 120, which includes dielectric layers 122 and metallization layers 124, facilitates electrical connections between the integrated circuit dies 130A, 130B, and other components within the package structure 100. These electrical connections may be formed through the metallization layers 124 and the through substrate vias 108, providing both horizontal and vertical electrical connectivity within the package structure 100.

In some embodiments, the integrated circuit dies 130A, 130B may be bonded to the interconnect structure 120 using a direct bonding process. This direct bonding process may include metal-to-metal bonding, dielectric-to-dielectric bonding, or any other suitable bonding technique. For example, dielectric layers of the integrated circuit dies 130A, 130B may be directly bonded to a topmost dielectric layer of the interconnect structure 120, and bond pads of the integrated circuit dies 130A, 130B may be directly bonded to the bond pads of the interconnect structure 120. In an embodiment, the bond between the dielectric layers may be an oxide-to-oxide bond, or the like. The direct bonding process further directly bonds the bond pads of the integrated circuit dies 130A, 130B to the bond pads of the interconnect structure 120 through direct metal-to-metal bonding. The direct bonding process may provide a strong and reliable bond between the integrated circuit dies 130A, 130B and the interconnect structure 120, potentially leading to improved performance and reliability of the package structure 100.

Each of the integrated circuit dies 130A, 130B may be a bare chip semiconductor die (e.g., unpackaged semiconductor die) that is formed as part of a larger wafer. For example, each of the integrated circuit dies 130A, 130B may be a logic die (e.g., application processor (AP), central processing unit, microcontroller, etc.), a memory die (e.g., dynamic random access memory (DRAM) die, hybrid memory cube (HBC), a static random access memory (SRAM) die, a wide input/output (wideIO) memory die, a magnetoresistive random access memory (mRAM) die, a resistive random access memory (rRAM) die, etc.), a power management die (e.g., power management integrated circuit (PMIC) dies), a radio frequency (RF) die, a sensor die, a micro-electro-mechanical-system (MEMS) die, a signal processing die (e.g., digital signal processing (DSP) die), a front-end die (e.g., analog front-end (AFE) die), a biomedical die, or the like.

Each of the integrated circuit dies 130A, 130B may be processed according to applicable manufacturing processes to form integrated circuits in the integrated circuit dies 130A, 130B. For example, each of the integrated circuit dies 130A, 130B may include a semiconductor substrate, such as silicon, doped or undoped, or an active layer of a semiconductor-on-insulator (SOI) substrate. The semiconductor substrate may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used.

Active and/or passive devices, such as transistors, diodes, capacitors, resistors, etc., may be formed in and/or on the semiconductor substrate. The devices may be interconnected by an interconnect structure comprising, for example, metallization patterns in one or more dielectric layers on the semiconductor substrate. The interconnect structures electrically connect the devices on the substrate to form one or more integrated circuits.

The integrated circuit dies 130A, 130B further comprises contact or bond pads, which allow connections to be made to the interconnect structure of the integrated circuit dies 130A, 130B and the devices on the substrate of the integrated circuit dies 130A, 130B. The contact pads may comprise copper, aluminum (e.g., 28K aluminum), gold, silver, or another conductive material.

The integrated circuit dies 130A, 130B may be formed as part of a larger wafer (e.g., connected to other integrated circuit dies 130). In some embodiments, the integrated circuit dies 130A, 130B may be singulated from each other after packaging. For example, the integrated circuit dies 130A, 130B may be packaged while still connected as part of a wafer. In other embodiments, the integrated circuit dies 130A, 130B may be packaged after it has been singulated from other components of the wafer. In some embodiments, a chip probe (CP) test may be applied to each of the integrated circuit dies 130A, 130B (e.g., through the contact or bond pads). The CP test checks electrical functionality of the integrated circuit dies 130A, 130B, and dies that pass the CP tests are referred to as known good dies (KGDs). Integrated circuit dies 130A, 130B that do not pass the CP tests are discarded or repaired. In this manner, KGDs are provided for packaging, which reduces waste and expense of packaging a faulty die.

The contact or bond pads of the integrated circuit dies 130A, 130B are bonded to bond pads of the bond surface 126 on the interconnect structure 120. The bonding pads may provide a site for electrical connection between the integrated circuit dies 130A, 130B and the interconnect structure 120.

In some embodiments, the plurality of chiplets, which may include integrated circuit die 130A and integrated circuit die 130B, may include at least one processor chiplet and at least one memory chiplet. In some embodiments, the plurality of chiplets further include a neural engine chiplet. This configuration may provide a flexible and efficient way to integrate various types of chiplets within the package structure 100, leading to improved performance and functionality of the package structure 100.

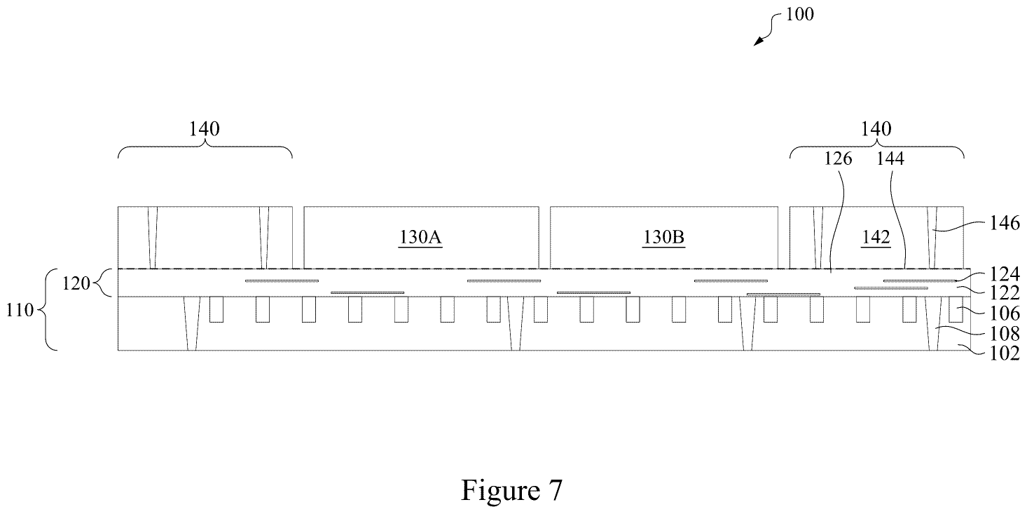

FIG. 7 illustrates bonding interposer dies 140 to the interposer 110 adjacent to the integrated circuit dies 130A and 130B. The interposer dies 140 may also be referred to as adapter interposer dies 140. Each interposer die 140 includes an interposer substrate 142 and bond pads 144. The interposer substrate 142 may be formed from various materials, such as silicon, glass, ceramic, or any other suitable material. The bond pads 144 may be formed from a conductive material, such as copper, gold, silver, or any other suitable conductive material. The bond pads 144 may provide a site for electrical connection between the interposer die 140 and other components of the package structure 100.

In some embodiments, the interposer dies 140 may include through substrate vias 146 that facilitate vertical electrical connections. The through substrate vias 146 may be similar to the through substrate vias 108 and the description is not repeated herein. The through substrate vias 146 may extend vertically through the interposer substrate 142, providing electrical connectivity between different layers or components of the package structure 100. In some embodiments, the through substrate vias 146 have a width in a range from 2 μm to 10 μm.

The interposer dies 140 may be formed by a similar process as the integrated circuit dies 130 and the description is not repeated herein. For example, the interposer dies 140 may be formed as part of a larger wafer and singulated into individual interposer dies 140. In some embodiments, the interposer dies 140 include passive devices such as capacitors, inductors, resistors, the like, or a combination thereof but do not include active devices. In some embodiments, the interposer dies 140 include active devices such as transistors interconnected to form circuitry.

In some embodiments, the interposer dies 140 may be bonded to the interconnect structure 120 by a direct bonding process. This direct bonding process may include metal-to-metal bonding, dielectric-to-dielectric bonding, or any other suitable bonding technique. The direct bonding process may provide a strong and reliable bond between the interposer dies 140 and the interconnect structure 120, potentially leading to improved performance and reliability of the package structure 100. Further, the interposer dies 140 may be bonded to the interconnect structure 120 using a similar direct bonding process described above and the description is not repeated herein.

In some embodiments, the method may include bonding a plurality of interposer dies, such as interposer die 140, with a direct bonding process to the interposer, such as interposer 110. The electrical connection between the interconnect structure, such as interconnect structure 120, of the interposer and the memory package, such as memory package 202, may include through substrate vias, such as through substrate via 146, in the plurality of interposer dies. This configuration may provide an efficient way to integrate various components within the package structure 100, potentially leading to improved performance and functionality of the package structure 100.

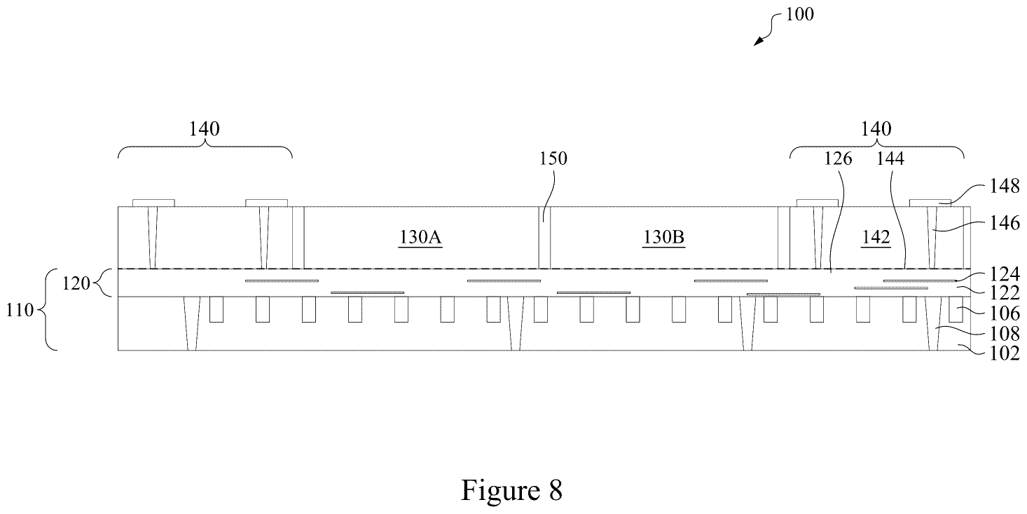

Referring to FIG. 8, the integrated circuit dies 130A, 130B and the interposer dies 140 are encapsulated with an encapsulant 150. The encapsulant 150 may be a molding compound, an oxide, or any other suitable material. The encapsulant 150 may provide structural support and environmental protection for the integrated circuit dies 130A, 130B and the interposer dies 140. In some embodiments, the encapsulant 150 may also provide electrical insulation between the integrated circuit dies 130A, 130B and the interposer dies 140.

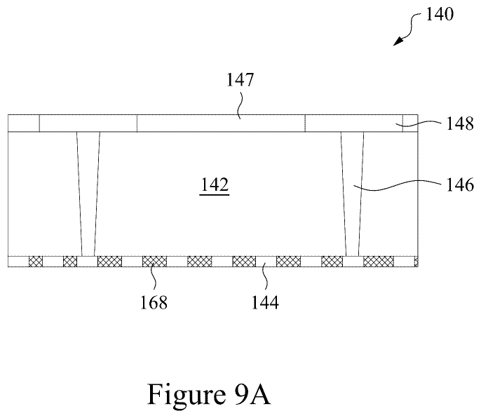

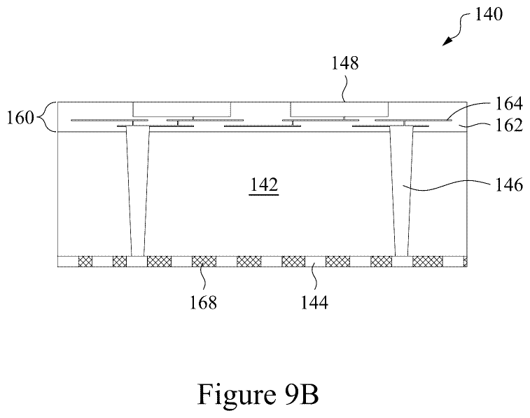

Bump pads 148 are formed on the top surface of the interposer dies 140 and are electrically connected to the through substrate vias 146. The bump pads 148 may be referred to as under-bump metallizations (UBMs) 148. The UBMs 148 are formed for external connection to the interposer dies 140. The UBMs 148 have bump portions on and extending along the top surface of the interposer die 140 (or an upper dielectric layer if present, see, e.g., FIGS. 9A and 9B) o, and have via portions extending into the interposer die 140 (or an upper dielectric layer if present) to physically and electrically couple the through substrate vias 146. As a result, the UBMs 148 are electrically connected to the interconnect 120 (e.g., through the through substrate vias 146). The UBMs 148 may be formed from a conductive material, such as copper, aluminum, tungsten, titanium, gold, silver, the like, or a combination thereof. The UBMs 148 may provide a site for electrical connection between the interposer die 140 and subsequently attached components, such as a memory package or other integrated circuit dies.

FIGS. 9A and 9B illustrate cross-sectional views of interposer dies 140 according to various embodiments. FIG. 9B includes an interconnect structure 160 on an upper surface of the interposer substrate 142 and FIG. 9A does not include the interconnect structure. Both embodiments illustrate bond pads 144 on the lower surface of the interposer substrate 142 being embedded in a dielectric layer 168. Further, both embodiments, illustrate the UBMs 148 being embedded in dielectric layers on the upper surface of the interposer die 140. In FIG. 9A, a dielectric layer 147 is laterally surrounding the UBMs 148 and in FIG. 9B, one of the dielectric layers 162 of the interconnect structure 160 is laterally surrounding the UBMs 148.

The interconnect structure includes dielectric layers 162 and metallization layer 164. The interconnect structure 160 may be similar to the interconnect structure 120 described above and the description is not repeated herein. Through substrate vias 146 extend vertically through the interposer substrate 142 and may be electrically coupled to the interconnect structure 160 and/or the UBMs 148.

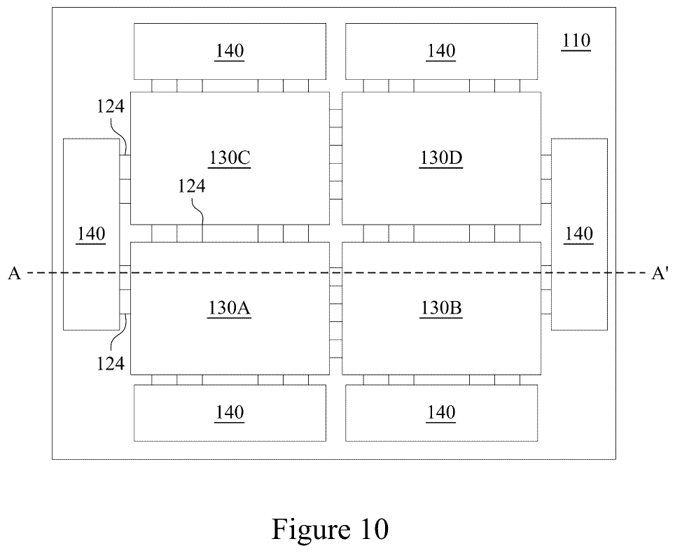

Referring now to FIG. 10, a top view of the interposer 110 is depicted with the structure of FIG. 8 being along the reference line A-A′ in FIG. 10. In some embodiments, the integrated circuit dies 130A, 130B, 130C, and 130D are centrally located on the interposer 110. These integrated circuit dies may include at least one processor chiplet and at least one memory chiplet. The specific types and configurations of the integrated circuit dies may vary depending on the specific requirements of the package structure 100. For instance, the integrated circuit dies may include a central processing unit (CPU), a graphics processing unit (GPU), a memory controller, a neural processing unit (NPU), or any other suitable type of processing or memory unit.

Adjacent to each of the integrated circuit dies are the interposer dies 140. The interposer dies 140 may be directly bonded to the interposer 110. Metallization layers 124 of the interconnect structure 120 electrically couple the integrated circuit dies 130 and the interposer dies 140. The metallization layers 124 may facilitate electrical connections between various components of the package structure 100, such as integrated circuit dies, memory packages, or other components. These electrical connections may be formed through the metallization layers 124 and the through substrate vias 108, providing both horizontal and vertical electrical connectivity within the package structure 100.

Although four integrated circuit dies or chiplets 130 are illustrated in FIG. 10, there may be more or less integrated circuit dies or chiplets 130 depending on the specific requirements of the package structure 100. Similarly, although four interposer dies 140 are illustrated, there may be more or less interposer dies 140 depending on the specific requirements of the package structure 100. The specific arrangement and configuration of the integrated circuit dies 130 and the interposer dies 140 on the interposer 110 may also vary, depending on the specific requirements of the package structure 100. For instance, the integrated circuit dies 130 and the interposer dies 140 may be arranged in a grid pattern, a staggered pattern, a random pattern, or any other suitable pattern. The size, shape, and spacing of the integrated circuit dies 130 and the interposer dies 140 may also be varied, depending on the specific requirements of the package structure 100.

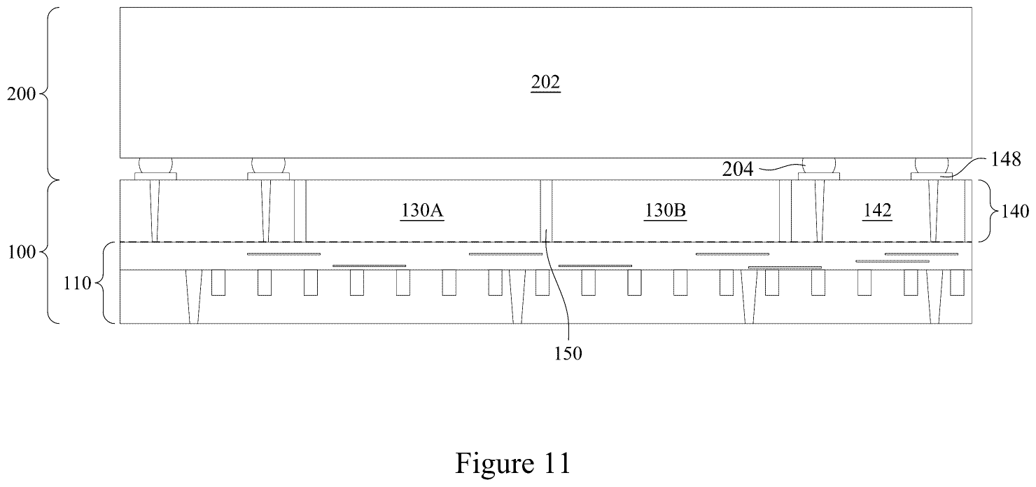

FIG. 11 illustrates the bonding of a package structure 200 to the package structure 100 using conductive connectors 204. The package structure 200 may include a memory package 202. In some embodiments, the memory package 202 may be a memory device, such as a dynamic random-access memory (DRAM) device, a static random-access memory (SRAM) device, a hybrid memory cube (HMC) module, a high bandwidth memory (HBM) module, a flash memory device, or any other suitable types of memory devices. The conductive connectors 204 provide electrical and physical connections between the package structure 100 and the memory package 202. The conductive connectors 204 may be bumps, such as controlled collapse chip connection (C4) bumps, solder balls, a ball grid array, or any other suitable type of conductive connectors.

Although package structure 200 is illustrated as having a singly memory device 202, other embodiments may have more structures in the package 200. For example, package 200 may include multiple memory devices 202, integrated circuit dies, support substrates, the like, or a combination thereof.

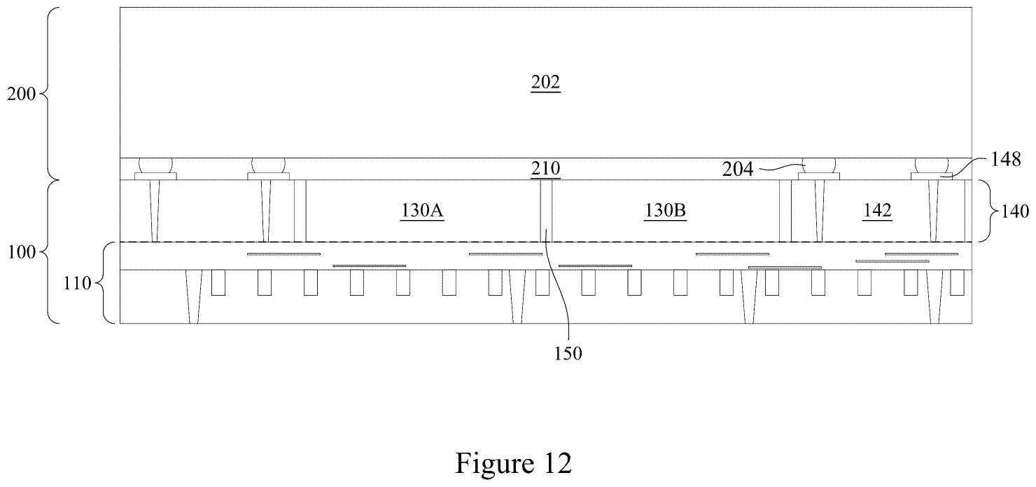

FIG. 12 illustrates the formation of an encapsulant 210 between the packages 100 and 200 and surrounding the conductive connectors 204. The encapsulant 210 may be a molding compound, an oxide, or any other suitable material. This process may involve various techniques known in the art, such as deposition, molding, or other suitable methods. The encapsulant 210 may be applied in different thicknesses or patterns, depending on the specific requirements of the package structure 100. The encapsulant 210 may provide structural support and environmental protection for the assembly. In some embodiments, the encapsulant 210 may also provide electrical insulation between the packages 100 and 200, leading to improved performance and reliability of the package structure 100.

The lower surface of the memory package 202, the upper portion of the integrated circuit dies 130A and 130B, and the conductive connectors 204 are encapsulated by the encapsulant 210. This encapsulation process may protect the integrated circuit dies 130A, 130B, the memory package 202, and the conductive connectors 204 from environmental factors, such as moisture, dust, or other contaminants, potentially leading to improved reliability and longevity of the package structure 100.

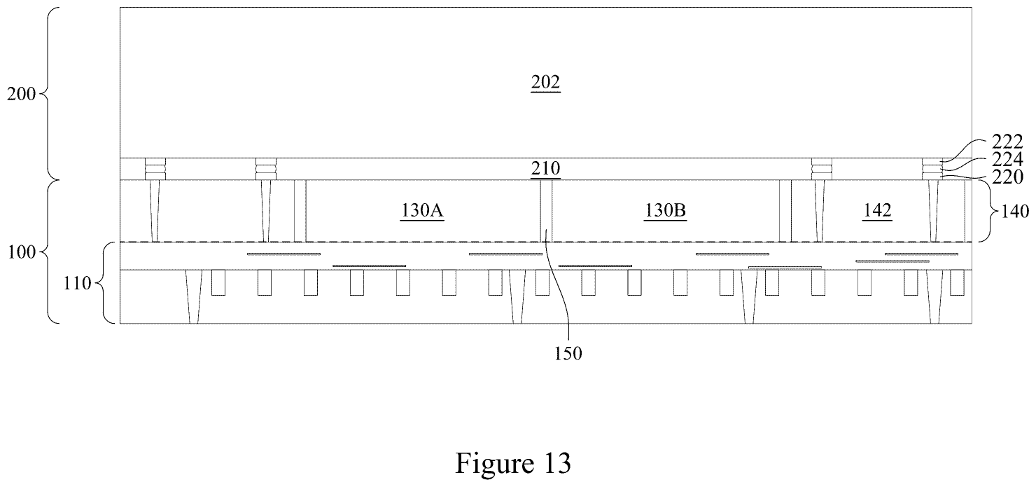

FIG. 13 illustrates a cross-sectional view of an intermediate stage in the formation of a package structure in accordance with some embodiments. In FIG. 13, like reference numerals indicate like elements formed by like processes as described above in FIGS. 1 through 12 unless otherwise indicated. In FIG. 13, the packages 100 and 200 are connected by conductive connectors 224 and UBMs 220 and 222.

The conductive connectors 224 may be formed on the UBMs 148. The conductive connectors 224 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 224 may include a conductive material such as solder, copper, aluminum, gold, nickel, silver, palladium, tin, the like, or a combination thereof. In some embodiments, the conductive connectors 224 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 224 comprise metal pillars (such as copper pillars) formed by a sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process. In a specific embodiment, the conductive connectors 224 and UBMs 220 and 222 are micro bumps structures.

The configuration of the package structure as depicted in FIG. 13 is one example of how the memory package 202 may be bonded to the interposer dies 140 using a micro bump bonding structure. Other configurations and arrangements of the memory package 202, the interposer dies 140, and the micro bump bonding structure are also possible, depending on the specific requirements of the package structure 100. For instance, the number, type, and arrangement of the micro bumps may be varied, and the memory package 202 may include additional features or components, depending on the specific requirements of the package structure.

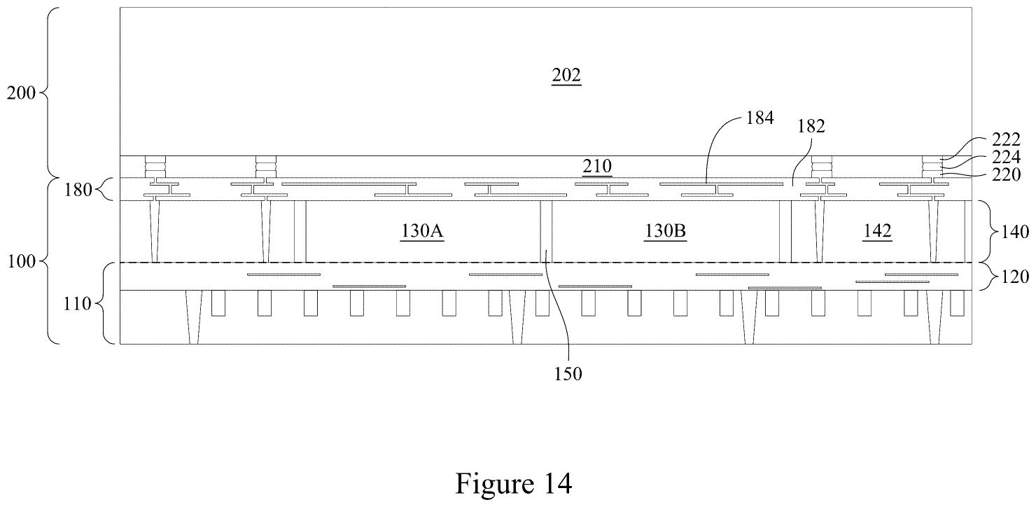

FIG. 14 illustrates a cross-sectional view of an intermediate stage in the formation of a package structure in accordance with some embodiments. In FIG. 14, like reference numerals indicate like elements formed by like processes as described above in FIGS. 1 through 13 unless otherwise indicated. In FIG. 14, the package structure 100 is similar to that of FIG. 13, with the addition of a redistribution structure 180. The redistribution structure 180 includes dielectric layers 182 and metallization layers 184, which facilitate the routing of electrical signals within the package structure 100.

The redistribution structure 180 is formed on the encapsulant 150 and the dies 130 and 140. The redistribution structure 180 may include redistribution lines (RDLs) 184, such as metal traces (or metal lines), and vias underlying and connected to the metal traces. The redistribution lines of the redistribution structure 180 are physically and electrically connected to the through substrate vias 146 of the interposer dies 140.

In some embodiments, the RDLs 184 are formed through plating processes, wherein each of the RDLs 184 includes a seed layer (not shown) and a plated metallic material over the seed layer. The seed layer may be formed using, for example, PVD or the like. A photoresist is then formed and patterned on the seed layer. The photoresist may be formed by spin coating or the like and may be exposed to light for patterning. The pattern of the photoresist corresponds to the RDLs 184. The patterning forms openings through the photoresist to expose the seed layer. A conductive material is formed in the openings of the photoresist and on the exposed portions of the seed layer. The conductive material may be formed by plating, such as electroplating or electroless plating, or the like. The seed layer and the plated metallic material may be formed of the same material or different materials. The conductive material may be a metal, like copper, titanium, tungsten, aluminum, or the like. Then, the photoresist and portions of the seed layer on which the conductive material is not formed are removed. Once the photoresist is removed, exposed portions of the seed layer are removed, such as by using an acceptable etching process, such as by wet and/or dry etching. The remaining portions of the seed layer and conductive material form the RDLs 184.

Dielectric or passivation layers 182 may be formed over each layer of the metal traces 184. In some embodiments, the dielectric or passivation layers 182 are formed of a polymer, which may be a photo-sensitive material such as polybenzoxazole (PBO), polyimide, benzocyclobutene (BCB), or the like, that may be patterned using a lithography mask. In other embodiments, the dielectric or passivation layers 182 are formed of a nitride such as silicon nitride; an oxide such as silicon oxide, phosphosilicate glass (PSG), borosilicate glass (BSG), boron-doped phosphosilicate glass (BPSG); or the like. The dielectric or passivation layers may be formed by spin coating, lamination, chemical vapor deposition (CVD), the like, or a combination thereof.

Openings may be formed in the top dielectric or passivation layer 182 with a patterning process, exposing some or all of the top metal layer 184 of the redistribution structure 180. The patterning process may be an acceptable process, such as by exposing the dielectric or passivation layer 182 to light when the dielectric layer is a photo-sensitive material or by etching using, for example, an anisotropic etch.

The redistribution structure 180 may provide a flexible and efficient way to route electrical signals between various components of the package structure 100, such as integrated circuit dies, memory packages, or other components. This may result in improved signal transmission, reduced signal delay, and increased bandwidth, potentially leading to improved performance of the package structure.

The redistribution structure 180 is illustrated as an example. More or fewer dielectric layers 182 and metallization layers 184 than illustrated may be formed in the redistribution structure 180 by repeating or omitting the steps previously described.

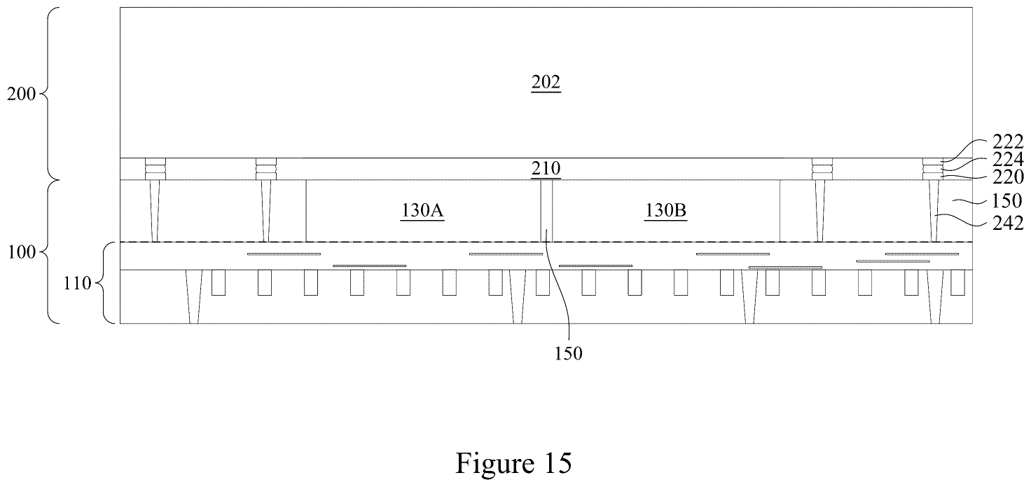

FIG. 15 illustrates a cross-sectional view of an intermediate stage in the formation of a package structure in accordance with some embodiments. In FIG. 15, like reference numerals indicate like elements formed by like processes as described above in FIGS. 1 through 14 unless otherwise indicated. In FIG. 15, the package structure 100 is similar to that of FIG. 13, except in the embodiment, the interposer dies 140 are not included in the package structure 100. In this configuration, the encapsulant 150 surrounds the integrated circuit dies 130A and 130B and through dielectric vias 242.

The through dielectric vias 242 extend through the encapsulant 150, enabling vertical electrical connectivity between the interposer 110, the integrated circuit dies 130A, 130B, and the memory package 202. The through dielectric vias 242 may be formed using various techniques known in the art, such as laser drilling, etching, or other suitable methods. The through dielectric vias 242 may be formed by patterning openings through the encapsulant 150 and forming a conductive material in the openings. The through dielectric vias 242 may be similar to the through substrate vias 108 and 146 and the description is not repeated herein. In some embodiments, the through dielectric vias 242 have a width in a range from 2 um to 10 um.

This configuration may provide an efficient way to integrate various components within the package structure 100, potentially leading to improved performance and functionality of the package structure 100. The configuration of the package structure as depicted in FIG. 15 is one example of how the integrated circuit dies 130A, 130B may be encapsulated with an encapsulant 150, and how the through dielectric vias 242 may be formed through the encapsulant 150. Other configurations and arrangements of the encapsulant 150 and the through dielectric vias 242 within the package structure are also possible, depending on the specific requirements of the package structure 100. For instance, the encapsulant 150 may be applied in different thicknesses or patterns, and the through dielectric vias 242 may be formed in different sizes, shapes, or arrangements, depending on the specific requirements of the package structure 100.

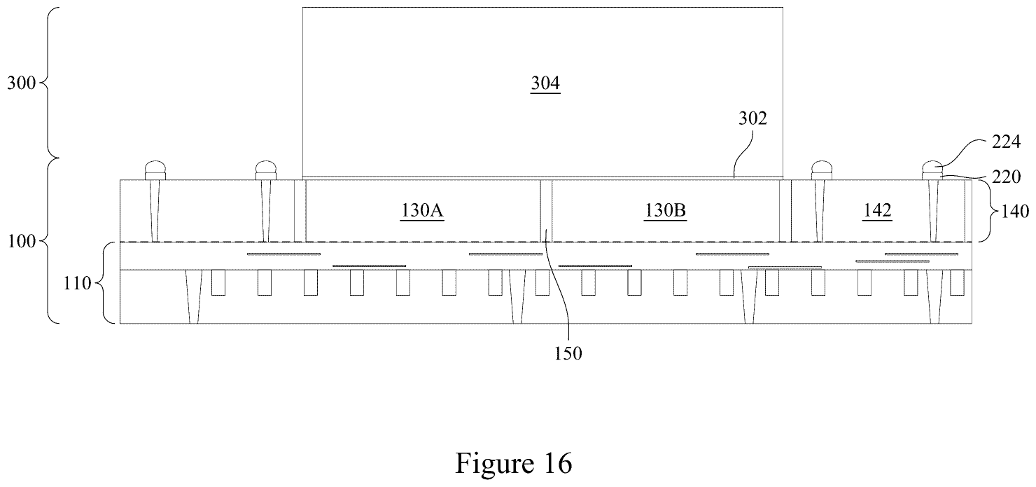

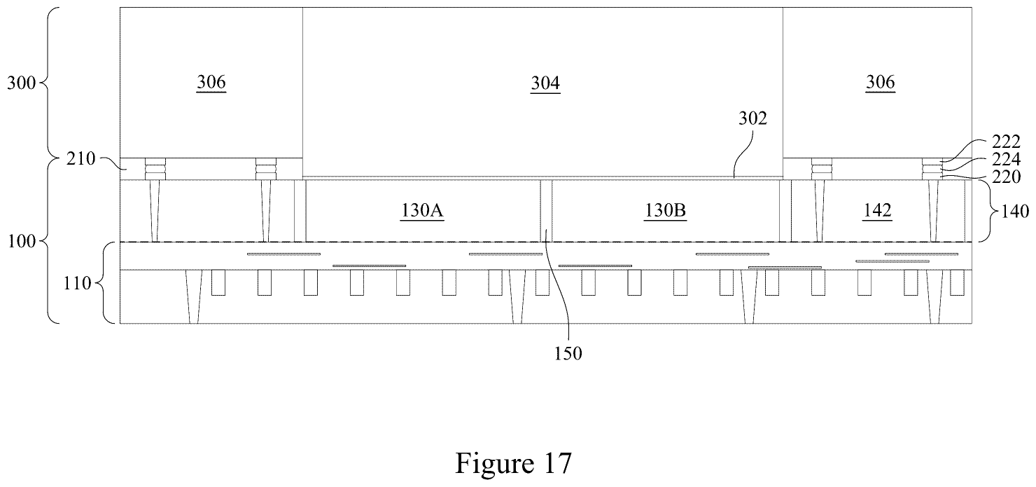

FIGS. 16 and 17 illustrates cross-sectional views of intermediate stages in the formation of a package structure in accordance with some embodiments. In FIGS. 16 and 17, like reference numerals indicate like elements formed by like processes as described above in FIGS. 1 through 15 unless otherwise indicated. In FIGS. 16 and 17, a package structure 300 is attached to the package structure 100 and the package structure 300 includes a support substrate 304 and multiple memory packages 306 surrounding the support substrate 304.

Referring now to FIG. 16, the package structure 100 is depicted in a similar stage of processing as FIG. 8 with the addition of the support substrate 304. In some embodiments, the support substrate 304 is attached to the package structure 100 with a thermal interface material 302.

The support substrate 304 may be formed from various materials, such as silicon, glass, ceramic, or any other suitable material. In some embodiments, the support substrate 304 may be attached over the plurality of chiplets, such as integrated circuit dies 130, with a thermal interface material 302. The thermal interface material 302 may be a thermally conductive material, such as a metal, a thermally conductive polymer, or any other suitable thermally conductive material. The thermal interface material 302 may provide a path for heat transfer from the integrated circuit dies 130 to the support substrate 304, leading to improved thermal management and performance of the package structure 100.

FIG. 17 illustrate bonding the memory packages 306 to the package structure 100 using UBMs 222 and conductive connectors 224. In some embodiments, the memory packages 306 are bonded adjacent to the support substrate 304. The memory packages 306 may be similar to the memory package 202 and the description is not repeated herein.

The support substrate 304 may provide structural support for the memory packages 306, potentially leading to improved reliability and longevity of the package structure 100. In some embodiments, the support substrate 304 may also provide a path for heat transfer from the memory packages 306 to the surrounding environment, potentially leading to improved thermal management and performance of the package structure 300.

An encapsulant 210 encapsulates the memory packages 306 and the support substrate 304. The encapsulant 210 may be similar to the encapsulant 150 and the description is not repeated herein. The encapsulant 210 may provide structural support and environmental protection for the memory packages 306 and the support substrate 304. In some embodiments, the encapsulant 210 may also provide electrical insulation between the memory packages 306, the support substrate 304, and other components of the package structure 100, potentially leading to improved performance and reliability of the package structure 100.

The configuration of the package structure 100 as depicted in FIG. 17 is one example of how the memory packages 306 may be bonded to the package structure 100 using UBMs 222 and conductive connectors 224. Other configurations and arrangements of the memory packages 306, the UBMs 222, the conductive connectors 224, the support substrate 304, and the encapsulant 210 within the package structure 100 are also possible, depending on the specific requirements of the package structure 100. For instance, the number, type, and arrangement of the memory packages 306, the UBMs 222, and the conductive connectors 224 may be varied, and the support substrate 304 and the encapsulant 210 may include additional features or components, depending on the specific requirements of the package structure.

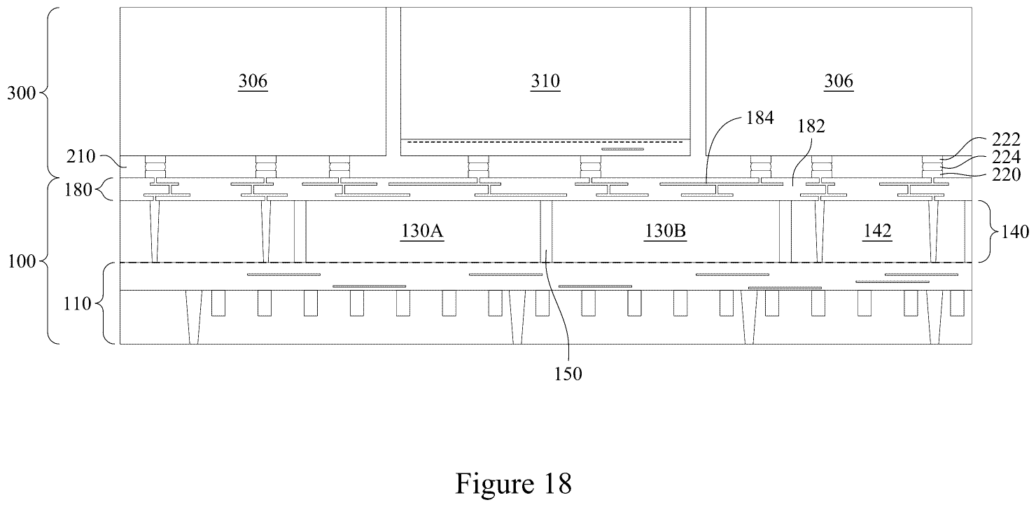

FIG. 18 illustrates a cross-sectional view of an intermediate stage in the formation of a package structure in accordance with some embodiments. In FIG. 18, like reference numerals indicate like elements formed by like processes as described above in FIGS. 1 through 17 unless otherwise indicated. In FIG. 18, the configuration is similar to that of FIG. 17, with the addition of the redistribution structure 180 over the dies 130 and 140 and an integrated circuit die 310 in the package structure 300.

In some embodiments, the package structure 300 includes an integrated circuit die 310 between the memory packages 306. The integrated circuit die 310 may be any type of integrated circuit die, such as a processor die, a memory die, a sensor die, or any other suitable type of integrated circuit die. In a specific embodiment, the die 310 is a power management IC (PMIC) die. The integrated circuit die 310 may be bonded to the package structure 100 using various techniques known in the art, such as solder bumping, wire bonding, flip-chip bonding, or any other suitable bonding techniques.

The configuration of the package structure as depicted in FIG. 18 is one example of how the redistribution structure 180 may be integrated within the package structure, and how the integrated circuit die 310 may be included between the memory packages 306. Other configurations and arrangements of the redistribution structure 180, the integrated circuit die 310, and the memory packages 306 within the package structure are also possible, depending on the specific requirements of the package structure. For instance, the redistribution structure 180 may include additional features or components, such as vias, contacts, or other interconnect elements, depending on the specific requirements of the package structure 100. Similarly, the integrated circuit die 310 and the memory packages 306 may include additional features or components, depending on the specific requirements of the package structure.

The embodiments in FIGS. 12 through 18 are example configurations but the disclosure is not limited to the specific configurations illustrated. For example, the embodiment of FIG. 15 can include the redistribution structure 180, the embodiments of FIGS. 17 and 18 can include the through dielectric vias 242. Further, each of the embodiments can undergo further processing to bond the interposer 110 to another structure, such as a package substrate with conductive connectors coupled to the through substrate vias 108 between the back-side 102B of the interposer 110 and the package substrate. Further, any embodiments including the interposer dies 140 may include active devices, passive devices, or a combination thereof in the interposer dies 140.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

In an embodiment, a semiconductor device may include an interposer. The semiconductor device may also include a plurality of chiplets directly bonded to the interposer. The device may furthermore include a plurality of interposer dies directly bonded to the interposer adjacent to the plurality of chiplets, the plurality of interposer dies having through-substrate vias. The device may additionally include a memory package over and bonded to at least one of the plurality of interposer dies.

The described embodiments may also include one or more of the following features: the semiconductor device where the interposer may include a silicon material; the semiconductor device where the plurality of chiplets includes at least one processor chiplet and at least one memory chiplet; the semiconductor device where the plurality of interposer dies includes passive components selected from the group having capacitors, resistors, and inductors; the semiconductor device where the memory package may include a dynamic random-access memory (DRAM) package; the semiconductor device may include a redistribution structure over the interposer, the redistribution structure including dielectric layers and metallization layers; the semiconductor device where the interposer further may include an interconnect structure with multiple dielectric layers and metallization layers, the metallization layers being electrically coupled to the plurality of chiplets and the plurality of interposer dies; the semiconductor device where the memory package is bonded to the at least one of the plurality of interposer dies using a micro bump bonding structure.

In an embodiment, a method may include directly bonding a plurality of chiplets to an interposer. The method may also include directly bonding a plurality of interposer dies to the interposer adjacent to the plurality of chiplets, where the plurality of interposer dies may include through-substrate vias. The method may furthermore include bonding a memory package over and to at least one of the plurality of interposer dies using a solder connection.

The described embodiments may also include one or more of the following features: the method where directly bonding the plurality of chiplets to the interposer may include metal-to-metal bonding and dielectric-to-dielectric bonding; the method where directly bonding the plurality of chiplets to the interposer includes bonding at least one processor chiplet and at least one memory chiplet; the method where directly bonding the plurality of interposer dies to the interposer includes integrating passive components into the plurality of interposer dies, the passive components selected from the group having capacitors, resistors, and inductors; the method where the plurality of interposer dies may include transistors; the method may include attaching a support substrate over the plurality of chiplets with a thermal interface material, the memory package being adjacent to the support substrate; the method may include forming an interconnect structure over the interposer, the interconnect structure having dielectric layers and metallization layers, the metallization layers of the interconnect structure being electrically coupled to the plurality of chiplets and the plurality of interposer dies; the method where bonding the memory package to the at least one of the plurality of interposer dies includes using a micro bump bonding structure.

In an embodiment, a method may include bonding with a direct bonding process a plurality of integrated circuit dies to an interposer, the interposer having through-substrate vias and an interconnect structure over the through-substrate vias, the interconnect structure having dielectric layers and metallization layers. The method may also include bonding a memory package over the plurality of integrated circuit dies. The method may furthermore include forming an electrical connection between the interconnect structure of the interposer and the memory package, the electrical connection being adjacent to the plurality of integrated circuit dies.

The described embodiments may also include one or more of the following features: the method may include bonding a plurality of interposer dies with a direct bonding process to the interposer, the electrical connection between the interconnect structure of the interposer and the memory package having through-substrate vias in the plurality of interposer dies; the method may include encapsulating the plurality of integrated circuit dies with an encapsulant and forming through-dielectric vias through the encapsulant, the electrical connection between the interconnect structure of the interposer and the memory package having the through-dielectric vias; the method attaching a support substrate over the plurality of integrated circuit dies with a thermal interface material, the memory package being adjacent to the support substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming an interconnect structure on an interposer substrate;
directly bonding multiple chiplets to a central region of the interconnect structure;
directly bonding adapter interposer dies with through substrate vias to a peripheral region of the interconnect structure surrounding the chiplets;
encapsulating the chiplets and adapter interposer dies with an encapsulant;
forming under-bump metallizations on top surfaces of the adapter interposer dies; and
bonding a memory package to the under-bump metallizations.

2. The method of claim 1, further comprising forming deep trench capacitors in the interposer substrate before forming the interconnect structure.

3. The method of claim 1, wherein the chiplets comprise at least one processor chiplet and at least one memory chiplet.

4. The method of claim 1, further comprising thinning a back-side of the interposer substrate to expose the through substrate vias.

5. The method of claim 1, wherein directly bonding the chiplets and adapter interposer dies comprises metal-to-metal bonding and dielectric-to-dielectric bonding.

6. The method of claim 1, further comprising forming a redistribution layer over the encapsulant and chiplets before forming the under-bump metallizations.

7. The method of claim 1, wherein bonding the memory package comprises forming conductive connectors between the under-bump metallizations and the memory package.

8. A semiconductor device comprising:
a first package including:
an interposer with directly bonded chiplets in a central region;
adapter dies with through substrate vias directly bonded to the interposer in a peripheral region surrounding the chiplets;
a second package including:
memory devices; and
a support substrate positioned between the memory devices;
wherein the memory devices are electrically connected to the chiplets via the through substrate vias in the adapter dies; and
a thermal interface material between the support substrate and the chiplets of the first package.

9. The semiconductor device of claim 8, wherein the interposer comprises deep trench capacitors.

10. The semiconductor device of claim 8, wherein the chiplets comprise at least one processor chiplet and at least one memory chiplet.

11. The semiconductor device of claim 8, further comprising an encapsulant surrounding the chiplets and adapter dies in the first package.

12. The semiconductor device of claim 8, further comprising under-bump metallizations on top surfaces of the adapter dies.

13. The semiconductor device of claim 8, further comprising conductive connectors between the adapter dies and the memory devices.

14. The semiconductor device of claim 8, further comprising a redistribution layer over the chiplets and adapter dies in the first package.

15. A method comprising:
forming an interconnect structure on an interposer substrate;
directly bonding different types of chiplets to a central region of the interconnect structure;
forming adapter interposer dies with through substrate vias;
directly bonding the adapter interposer dies to a peripheral region of the interconnect structure surrounding the chiplets;
encapsulating the chiplets and adapter interposer dies with an encapsulant;
forming a redistribution layer over the encapsulant and chiplets;
forming under-bump metallizations on the adapter interposer dies; and
bonding a memory package to the under-bump metallizations, electrically coupling the memory package to the chiplets via the adapter interposer dies and redistribution layer.

16. The method of claim 15, wherein the different types of chiplets comprise at least one processor chiplet and at least one memory chiplet.

17. The method of claim 15, further comprising forming deep trench capacitors in the interposer substrate before forming the interconnect structure.

18. The method of claim 15, wherein directly bonding the chiplets and adapter interposer dies comprises metal-to-metal bonding and dielectric-to-dielectric bonding.

19. The method of claim 15, further comprising thinning a back-side of the interposer substrate to expose the through substrate vias.

20. The method of claim 15, wherein bonding the memory package comprises forming conductive connectors between the under-bump metallizations and the memory package.
